(19) United States
(12) Patent Application Publication
(10) Pub. No.: US 2009/0029519 A1
(43) Pub. Date: Jan. 29, 2009

(54) METHOD OF MANUFACTURING MIM CAPACITOR

(76) Inventor: Joo-Hyun Lee, Icheon-si (KR)

Correspondence Address: SHERR & VAUGHN, PLLC, 620 HERNDON PARKWAY, SUITE 200, HERNDON, VA, 20170, US

(21) Appl. No.: 12/169,596

(22) Filed: Jul. 8, 2008

(30) Foreign Application Priority Data
Jul. 23, 2007 (KR) 10-2007-0073432

(51) Int. Cl. H01L 21/02

(52) U.S. Cl. 438/393; 257/E21.011

(57) ABSTRACT

Embodiments relate to a method of manufacturing an MIM capacitor, which is capable of obtaining a desired capacitance by controlling a k value of insulator thin film formed between bottom and top electrodes by adjusting a plasma doping condition. An MIM capacitor may be manufactured by forming a bottom electrode over a semiconductor substrate. An insulator thin film may be formed over the bottom electrode. A k value of the insulator thin film may be adjusted to an optional range by performing a plasma nitridation doping process on the insulator thin film. A top electrode may be formed over the insulator thin film.

The present application claims priority under 35 U.S.C. 119 to Korean Patent Application No. 10-2007-0073432 (filed on Jul. 23, 2007), which is hereby incorporated by reference in its entirety.

### BACKGROUND

Research and development of semiconductor devices has focused on boosting capacitance values in capacitors for high speed logic circuits. When a capacitor has a PIP (Polysilicon/Insulator/Polysilicon) structure, top and bottom electrodes of a capacitor are made of conductive polysilicon. An oxidation reaction occurs on an interface between the top and bottom electrodes and the insulator thin film, producing a natural oxide layer. This causes a reduction in overall capacitance.

The structure of a capacitor may be changed from PIP to MIM to solve this shortcoming. The MIM capacitor has a relatively small resistance and does not have a parasitic capacitance caused by an interior depletion. The MIM capacitor is mainly used in high-performance semiconductor devices requiring a relatively high Q value, i.e., RF CMOS devices.

To change a capacitance value when using a MIM capacitor structure, a thin film insulator must be changed or the design size must be changed. Such a change of insulator thin film or design size to alter a value of MIM capacitor is costly, and may require the purchase of new equipment or manufacture of a new mask.

### SUMMARY

Embodiments relate to a method of manufacturing an MIM (Metal/Insulator/Metal) capacitor, and more particularly, to a method of obtaining a desired capacitance by controlling a k-value of insulator through a plasma doping scheme. Embodiments relate to a method of manufacturing an MIM capacitor, which is capable of obtaining a desired capacitance by controlling a k value of insulator thin film formed between bottom and top electrodes through a use of plasma doping condition.

Embodiments relate to a method of manufacturing an MIM capacitor by forming a bottom electrode over a semiconductor substrate. An insulator thin film may be formed over the bottom electrode. A k value of the insulator thin film may be adjusted to an optional range by performing a plasma nitridation doping process on the insulator thin film. A top electrode may be formed over the insulator thin film.

Embodiments relate to a method of manufacturing an MIM capacitor by forming a bottom electrode over a semiconductor substrate. An insulator thin film may be formed over the bottom electrode. A k value of the insulator thin film may be adjusted to an optional range by performing a plasma nitrogen implantation process on the insulator thin film. Then, a top electrode may be formed over the insulator thin film.

### DRAWINGS

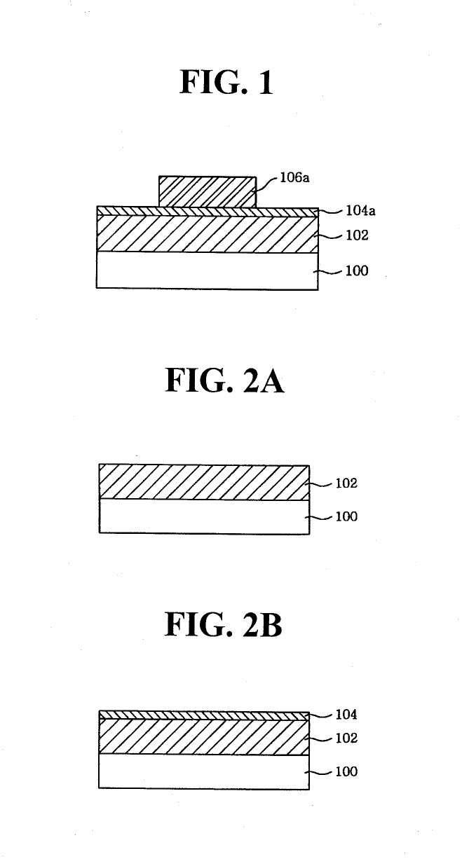

Example FIG. 1 is a longitudinal sectional view of MIM capacitor structure in a semiconductor device according to embodiments.

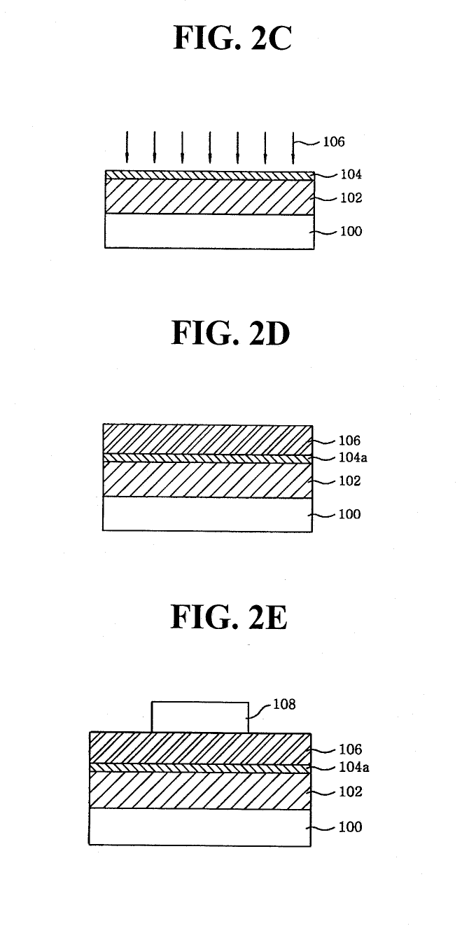

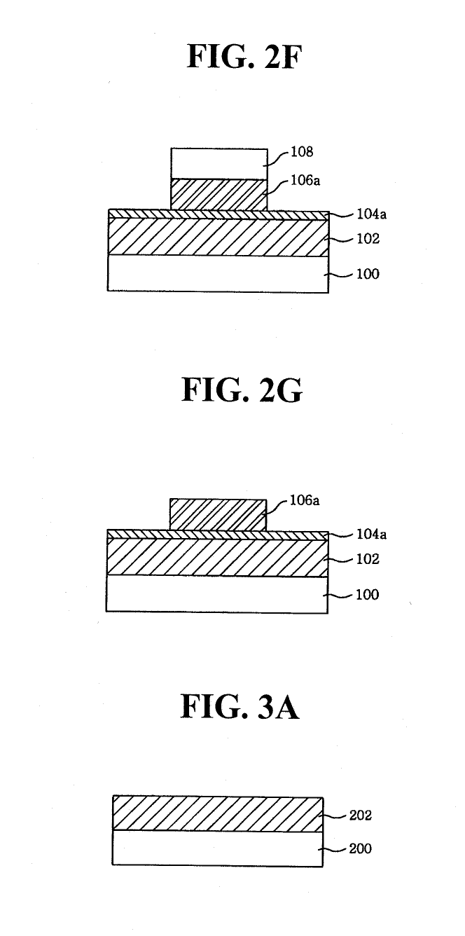

Example FIGS. 2A to 2G are longitudinal sectional views for respective processes providing an MIM capacitor manufacturing method of a semiconductor device according to embodiments.

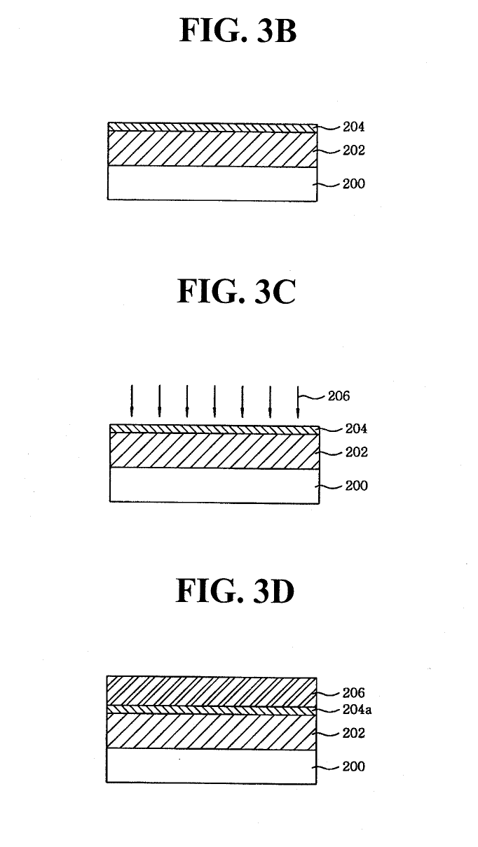

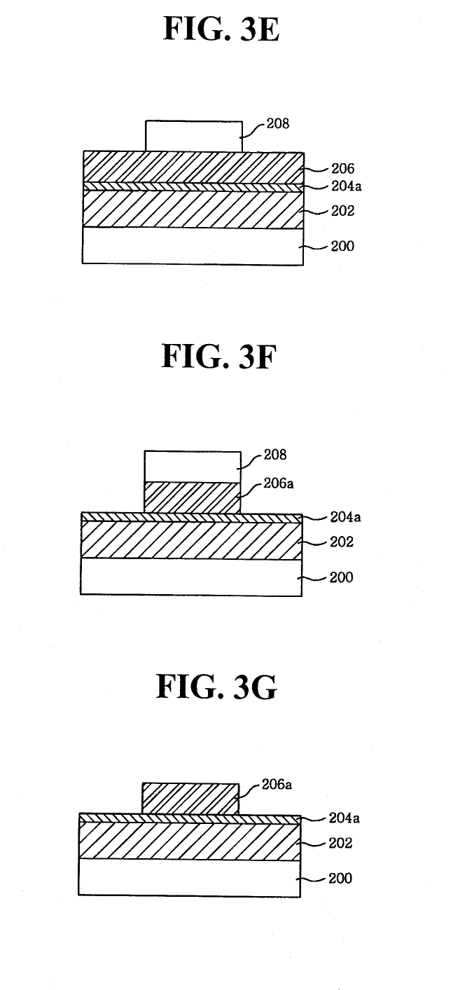

Example FIGS. 3A to 3G are longitudinal sectional views for respective processes in an MIM capacitor manufacturing method of a semiconductor device according to embodiments.

### DESCRIPTION

Example FIG. 1 is a longitudinal sectional view of MIM capacitor structure in a semiconductor device according to embodiments. Referring to example FIG. 1, in an MIM capacitor for use in a semiconductor device according to embodiments, a semiconductor logic circuit device is formed over a semiconductor substrate, and an interlayer insulation layer 100 is formed thereon. Over the interlayer insulation layer 100, a bottom electrode 102 of a capacitor is formed of a lower metal layer. An insulator thin film 104 obtained by adjusting a k value within an optional range, i.e., 3.9˜7.0, by setting a plasma doping condition is stacked over the bottom electrode 102. A top electrode 106a of the capacitor is formed with an upper metal layer, stacked over the insulator thin film 104.

Example FIGS. 2A to 2G are longitudinal sectional views for respective processes providing an MIM capacitor manufacturing method of a semiconductor device according to embodiments. With reference to example FIGS. 2A to 2G, a manufacture process of MIM capacitor for use in a semiconductor device according to an embodiment is described as follows. As shown in example FIG. 2A, a general semiconductor logic process is performed on a substrate, for example a silicon substrate, and an interlayer insulation layer 100 for insulation between devices is formed.

On the interlayer insulation layer 100, for example, Cu may be deposited as a lower metal layer. A photolithography and dry etching process may be performed thereon, to pattern the lower metal layer, thereby forming bottom electrode 102 of capacitor. Then, a silicon oxide layer SiO₂ may be deposited as an insulator thin film 104 over the bottom electrode 102 as shown in example FIG. 2B. A plasma doping process (106) may be performed over the insulator thin film 104 as shown in example FIG. 2C. For example, a plasma nitridation process may be performed with N₂ gas within a range of 0.1˜2 SLM and Ar gas within a range of 0.1˜1 SLM. The plasma doping may occur for a time within a range of about 10 seconds ˜600 seconds, and a temperature within a range of about 100° C.˜500° C., and pressure within a range of about 10˜300 Pa and microwave power within a range of about 700˜3300 W.

Then, in the silicon oxide layer, the k value of the insulator thin film 104 may be adjusted by changing a permittivity (ε) of insulator thin film within an optional range, i.e., 3.9˜7.0 through the plasma nitridation process, as shown in the following mathematical expression 1.

$$C = {ɛɛ}_{0} \frac{A}{d} \qquad Mathematical Expression 1$$

Here, in k=ε/ε₀, ε indicates the permittivity of insulator thin film 104, and ε₀ denotes the permittivity of vacuum, and C indicates capacitance, and A denotes the area of the capacitor, and d represents the thickness of insulator thin film 104.

Subsequently, a Ti or TiN layer may be deposited over the insulator thin film 104a, for which the k value has been adjusted to an optional range, to form an upper metal layer 106 as shown in example FIG. 2D. Then, the upper metal layer 106 is covered over with photoresist (PR), and an exposure and developing process is performed, thereby forming a PR pattern 108 defining a top electrode of a capacitor as shown in example FIG. 2E. The upper metal layer 106 may be patterned through an etching process, for example, reactive ion etching (RIE) using plasma, by using PR pattern 108 as a mask, thereby forming the top electrode 106a of a capacitor as shown in example FIG. 2F. Then, the PR pattern 108 may be removed through a process such as ashing etc. as shown in example FIG. 2G.

Example FIGS. 3A to 3G are longitudinal sectional views for respective processes in a method of manufacturing an MIM capacitor of a semiconductor device according to embodiments. With reference to example FIGS. 3A to 3G, a MIM capacitor of a semiconductor device according to embodiments may be manufactured through processes described below. First, as shown in example FIG. 3A, a general semiconductor logic process is performed on a substrate, for example a silicon substrate, and an interlayer insulation layer 200 is formed for insulation between devices.

On the interlayer insulation layer 200, for example, Cu may be deposited as a lower metal layer. A photolithography and dry etching process may be performed thereon, to pattern the lower metal layer, thereby forming bottom electrode 202 of capacitor. Then, a silicon oxide layer SiO₂ may be deposited as an insulator thin film 204 over the bottom electrode 202 as shown in example FIG. 3B. A plasma doping process (206) may be performed over the insulator thin film 104 as shown in example FIG. 3C. For example, a plasma nitridation implantation process may be performed with N₂ gas within a range of about 0.1˜2 SLM and Ar gas within a range of 0.1˜1 SLM. The plasma doping may occur for a time within a range of about 10 seconds ˜600 seconds, and a temperature within a range of about 100° C.˜500° C., and pressure within a range of about 10˜300 Pa. Energy may be set within a range of about 0.1 eV˜10 KeV. Then, in the silicon oxide layer, a k value of the insulator thin film 204 may be adjusted in an optional range, i.e., 3.9˜7.0, through plasma nitrogen implantation process, as shown in the above-mentioned mathematical expression 1.

Subsequently, a Ti or TiN layer may be deposited over the insulator thin film 204a, for which the k value has been adjusted to an optional range, to form an upper metal layer 206 as shown in example FIG. 3D. Then, the upper metal layer 206 is covered over with photoresist (PR), and an exposure and developing process is performed, thereby forming a PR pattern 208 defining a top electrode of a capacitor as shown in example FIG. 3E. The upper metal layer 206 may be patterned through an etching process, for example, reactive ion etching (RIE) using plasma, by using PR pattern 208 as a mask, thereby forming the top electrode 206a of a capacitor as shown in example FIG. 3F. Then, the PR pattern 208 may be removed through a process such as ashing etc. as shown in example FIG. 3G.

According to embodiments, a k value of insulator thin film formed of silicon oxide SiO₂ between top and bottom electrodes may be adjusted by setting a plasma doping condition, thereby liberally controlling a capacitance value in an optional range of about 3.9 to 7.0 within a similar physical structure. In other words, according to embodiments, a capacitance value can be adjusted liberally in a range of 3.9 to 7.0 within the same general physical structure, by controlling a k-value of insulator thin film formed of silicon oxide SiO₂ between top and bottom electrodes through a plasma nitridation or plasma nitrogen implantation process by adjusting a plasma doping condition.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a bottom electrode over a semiconductor substrate;
forming an insulator thin film over the bottom electrode;
adjusting a k value of the insulator thin film to an optional range by performing a plasma nitridation doping process on the insulator thin film; and
forming a top electrode over the insulator thin film.

2. The method of claim 1, wherein the k value of the insulator thin film is characterized in that a permittivity of the insulator thin film is changed to an optional range.

3. The method of claim 1, wherein the optional range is between approximately 3.9 and 7.0.

4. The method of claim 1, wherein the plasma nitridation doping process is performed:
with N₂ gas between approximately 0.1 SLM and 2 SLM;
with Ar gas between approximately 0.1 SLM and 1 SLM; and
at a pressure between approximately 10 Pa and 300 Pa.

5. The method of claim 1, wherein the plasma nitridation doping process is performed over a period of time between approximately 10 seconds and 600 seconds.

6. The method of claim 1, wherein the plasma nitridation doping process is performed at a temperature between approximately 100° C. and 500° C.

7. The method of claim 1, wherein the plasma nitridation doping process is performed with microwave power between approximately 700 W and 3300 W.

8. The method of claim 1, wherein the insulator thin film is a silicon oxide layer (SiO₂).

9. The method of claim 1, wherein the top electrode and the bottom electrode are formed of metal.

10. The method of claim 9, wherein the metal is copper.

11. A method comprising:
forming a bottom electrode over a semiconductor substrate;
forming an insulator thin film over the bottom electrode;
adjusting a k value of the insulator thin film to an optional range by performing a plasma nitrogen implantation process on the insulator thin film; and
forming a top electrode over the insulator thin film.

12. The method of claim 11, wherein the k value of the insulator thin film is characterized in that a permittivity of the insulator thin film is changed to an optional range.

13. The method of claim 11, wherein the optional range is between approximately 3.9 and 7.0.

14. The method of claim 11, wherein the plasma nitrogen implantation process is performed with N₂ gas between approximately 0.1 SLM and 2 SLM, at a pressure between approximately 10 Pa and 300 Pa.

15. The method of claim 11, wherein the plasma nitrogen implantation process is performed with energy between approximately 0.1 eV and 10 KeV.

16. The method of claim 11, wherein the plasma nitrogen implantation process is performed over a time period between approximately 10 seconds and 600 seconds.

17. The method of claim 11, wherein the plasma nitrogen implantation process is performed at a temperature between approximately 100° C. and 500° C.

18. The method of claim 11, wherein the insulator thin film is a silicon oxide layer (SiO₂).

19. The method of claim 11, wherein the top electrode and the bottom electrode are formed of metal.

20. The method of claim 19, wherein the metal is copper.
